(19) United States
(12) Patent Application Publication
(10) Pub. No.: US 2021/0104448 A1
(43) Pub. Date: Apr. 8, 2021

(54) LATERAL HEAT REMOVAL FOR 3D STACK THERMAL MANAGEMENT

(71) Applicant: Intel Corporation, Santa Clara, CA (US)

(72) Inventors: Feras EID, Chandler, AZ (US); Chandra Mohan JHA, Tempe, AZ (US); Je-Young CHANG, Tempe, AZ (US)

(21) Appl. No.: 16/596,377

(22) Filed: Oct. 8, 2019

(51) Int. Cl. H01L 23/367; H01L 23/427; H01L 23/373; H05K 7/20

(52) U.S. Cl. CPC H01L 23/3675; H01L 23/427; H05K 7/20409; H05K 7/20472; H01L 23/3737

(57) ABSTRACT

Embodiments include semiconductor packages. A semiconductor package includes a lateral heat spreader (LHS) over a package substrate, and a first die over the LHS and package substrate. The first die has a first region and a second region, where the first and second regions are on a bottom surface of the first die. The semiconductor package includes a plurality of second dies over the first die, and an integrated heat spreader (IHS) over the second dies, first die, LHS, and package substrate. The IHS includes a lid and legs. The LHS thermally couples the first region of the first die to the legs of the IHS, and laterally extends from below the first region of the first die to below the legs of the IHS. The LHS may be comprised of graphene sheets, heat pipes, or vapor chambers and coupled to a thermal conductive material and a sealant.

### FIELD

Embodiments relate to packaging semiconductor devices. More particularly, the embodiments relate to semiconductor devices with lateral heat spreaders for three-dimensional (3D) stack thermal management.

### BACKGROUND

For the past several decades, the scaling of features in integrated circuits (ICs) has been a driving force behind an ever-growing semiconductor industry. Scaling to smaller and smaller features enables increased densities of functional units on the limited real estate of semiconductor devices (or microelectronic devices). For example, higher performance, lower cost, and greater packaging density of ICs are ongoing goals of the semiconductor industry. To achieve these goals, semiconductor devices are continuously miniaturized and/or stacked to implement three-dimensional (3D) packages (or 3D architectures).

Furthermore, the drive to scale-down features in ICs such as 3D packages, while optimizing the performance of each device, however is not without issue. In such 3D packages, where multiple single dies or stacked dies are assembled onto a single package, existing packaging technologies encounter various problems which typically involve thermal issues, thermal management issues, and so on. Thermal management challenges arise in these 3D packages due to the high power density of the electrical components, the compounding impact of hotspots from multiple dies, and the high thermal resistance especially experienced by the lower components of the stack as the heat moves up through the low conductivity layers (e.g., the layers of underfill materials, mold materials, etc.). Also, when the temperature of the semiconductor devices becomes too high, the ICs of such semiconductor devices can become damaged, destroyed, and lead to additional issues.

One packaging solution includes using a traditional integrated heat spreader (IHS) to interface with the top dies through a thermal interface material (TIM) layer. This traditional packaging solution, however, is no longer viable as the IHS only interfaces with the top dies via the TIM layer—and the bottom dies are thus not adequately thermally managed. Other previous existing packaging solutions include using better TIM materials such as solder TIM, or higher conductivity underfill materials or mold materials, to reduce the total thermal resistance faced by the bottom dies in the 3D packages. While the existing packaging solutions above can provide some incremental improvements in performance, such packaging solutions do not scale with the future generations as the power dissipated by the dies continues to increase. This is especially evident for the bottom dies of the 3D packages which do not have adequate or direct heat transfer paths.

### BRIEF DESCRIPTION OF THE DRAWINGS

Embodiments described herein are illustrated by way of example and not limitation in the figures of the accompanying drawings, in which like references indicate similar features. Furthermore, some conventional details have been omitted so as not to obscure from the inventive concepts described herein.

FIG. 1 is an illustration of a cross-sectional view of a semiconductor package with an integrated heat spreader (IHS), a thermal interface material (TIM), an encapsulation layer, a first die, a plurality of second dies, a lateral heat spreader (LHS), a thermal conductive material, a sealant, and a package substrate, according to one embodiment.

FIG. 2A is an illustration of a plan view of a bottom surface of a first die with a plurality of first regions and a second region, where the first and second regions implement a first-level interconnect (FLI) pattern, according to one embodiment.

FIG. 2B is an illustration of a plan view of a bottom surface of a first die with a plurality of first regions and a plurality of second regions, where the first and second regions implement a FLI pattern, according to one embodiment.

FIG. 3 is an illustration of a cross-sectional view of a semiconductor package with an IHS, a TIM, an encapsulation layer, a first die, a plurality of second dies, a LHS, a thermal conductive material, a sealant, and a package substrate with a plurality of thermal vias, according to one embodiment.

FIG. 4 is an illustration of a schematic block diagram illustrating a computer system that utilizes a semiconductor package with an IHS, a TIM, an encapsulation layer, a first die, a plurality of second dies, a LHS, a thermal conductive material, a sealant, and a package substrate, according to one embodiment.

### DETAILED DESCRIPTION

Described herein are semiconductor packages with lateral heat spreaders (LHSs) and methods of forming such semiconductor packages with the LHSs. The semiconductor packages described below and methods of forming such semiconductor packages include an integrated heat spreader (IHS), a thermal interface material (TIM), an encapsulation layer, a first die (or a bottom die), a plurality of second dies (or top dies), a LHS, a thermal conductive material, a sealant, and a package substrate, according to some embodiments. The embodiments of the semiconductor packages described herein may implement a three-dimensional (3D) architecture comprised of a stack of first and second dies, and may thermally couple the first die of the stack to the IHS with the LHS to provide one or more additional heat removal paths.

As used herein, a “lateral heat spreader” may refer to a layer, a region, and/or a component (or the like) comprised of one or more thermal materials with high in-plane (or lateral, x-y plane, etc.) thermal conductivity, where such layer, region and/or component may thus help manage/improve the thermal properties of a semiconductor package (or a 3D stack package). For example, in the existing 3D stack package, the bottom die(s) of the stack may suffer from thermal issues/challenges as the heat from the bottom die(s) usually travels all the way up through the low conductivity layer(s) (e.g., the underfill layer, the encapsulation layer, etc.), the top dies, and the TIM prior to reaching the IHS. Accordingly, the thermal resistances of such layers, top dies, and TIMs generally add up to produce a high total thermal resistance encountered by the bottom dies of the stack, which may thus cause significantly increased temperatures at the bottom dies and lead to undesired throttling.

Instead, to overcome these issues, the embodiments described herein implement the LHS with high in-plane thermal conductivity to enable a direct heat transfer path between the first die(s) (or the bottom dies) and the IHS. Furthermore, the embodiments described herein provide improvements to existing packaging solutions by providing additional, direct heat transfer paths for the heat removal of the bottom dies of the stack. Additionally, the embodiments described below provide improvements to packaging solutions by enabling a 3D stack thermal management with both a lateral heat removal path and a vertical heat removal path for the stack of first and second dies of the semiconductor package. Accordingly, these embodiments described herein enable the semiconductor package to efficiently and laterally remove the heat from the bottom dies of the 3D stack through a direct heat transfer path, instead of the heat having to vertically go through a high thermal resistance path comprised of underfill/mold layers, top dies, and TIMs.

The technologies described herein may be implemented in one or more electronic devices. Non-limiting examples of electronic devices that may utilize the technologies described herein include any kind of mobile device and/or stationary device, such as microelectromechanical systems (MEMS) based electrical systems, gyroscopes, advanced driving assistance systems (ADAS), 5G communication systems, cameras, cell phones, computer terminals, desktop computers, electronic readers, facsimile machines, kiosks, netbook computers, notebook computers, internet devices, payment terminals, personal digital assistants, media players and/or recorders, servers (e.g., blade server, rack mount server, combinations thereof, etc.), set-top boxes, smart phones, tablet personal computers, ultra-mobile personal computers, wired telephones, combinations thereof, and the like. Such devices may be portable or stationary. In some embodiments, the technologies described herein may be employed in a desktop computer, laptop computer, smart phone, tablet computer, netbook computer, notebook computer, personal digital assistant, server, combinations thereof, and the like. More generally, the technologies described herein may be employed in any of a variety of electronic devices, including semiconductor packages with IHSs, TIMs, encapsulation layers, first dies (or bottom dies), second dies (or top dies), LHSs, thermal conductive materials, sealants, and package substrates with thermal vias.

In the following description, various aspects of the illustrative implementations will be described using terms commonly employed by those skilled in the art to convey the substance of their work to others skilled in the art. However, it will be apparent to those skilled in the art that the present embodiments may be practiced with only some of the described aspects. For purposes of explanation, specific numbers, materials and configurations are set forth in order to provide a thorough understanding of the illustrative implementations. However, it will be apparent to one skilled in the art that the present embodiments may be practiced without the specific details. In other instances, well-known features are omitted or simplified in order not to obscure the illustrative implementations.

Various operations will be described as multiple discrete operations, in turn, in a manner that is most helpful in understanding the present embodiments, however, the order of description should not be construed to imply that these operations are necessarily order dependent. In particular, these operations need not be performed in the order of presentation.

As used herein the terms “top,” “bottom,” “upper,” “lower,” “lowermost,” and “uppermost” when used in relationship to one or more elements are intended to convey a relative rather than absolute physical configuration. Thus, an element described as an “uppermost element” or a “top element” in a device may instead form the “lowermost element” or “bottom element” in the device when the device is inverted. Similarly, an element described as the “lowermost element” or “bottom element” in the device may instead form the “uppermost element” or “top element” in the device when the device is inverted.

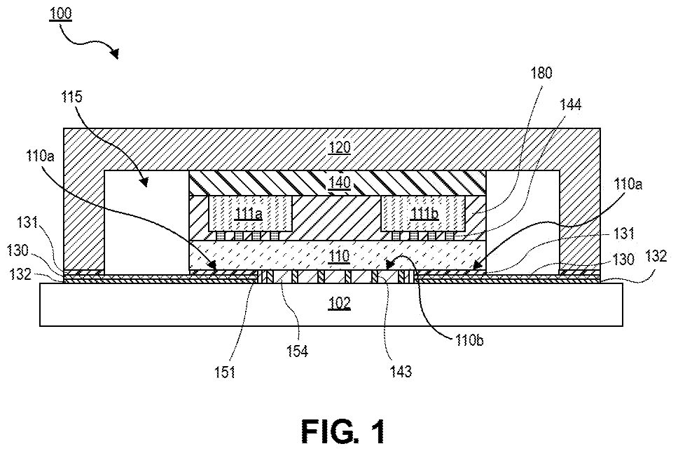

Referring now to FIG. 1, a cross-sectional illustration of a semiconductor package 100 is shown, in accordance with an embodiment. In an embodiment, the semiconductor package 100 may include an IHS 120, a TIM 140, an encapsulation layer 180, a first die 110, a plurality of second dies 111a-b, a LHS 130, a thermal conductive material 131, a sealant 132, and a package substrate 102, according to one embodiment. In these embodiments, the semiconductor package 100 may implement a stack of first and second dies 110 and 111a-b over the package substrate 102, where the second dies 111a-b are stacked on/over the first die 110. For one embodiment, the encapsulation layer 180 may be disposed over and around the first and second dies 110 and 111a-b, where the encapsulation layer 180 surrounds (or embeds) the second dies 111a-b.

In an embodiment, the TIM 140 may be disposed on the encapsulation layer 180 and the second dies 111a-b. Furthermore, the IHS 120 may be disposed over the TIM 140 and the package substrate 102, where the IHS 120 may form a cavity 115 that surrounds the first die 110, the second dies 111a-b, the encapsulation layer 180, and the TIM 140. As shown in FIG. 1, the first die 110 and the IHS 120 may be disposed over the thermal conductive material 131, the LHS 130, and the sealant 132. In particular, in these embodiments, the LHS 130 may be directly disposed between the thermal conductive material 131 and the sealant 132, where the thermal conductive material 131 may be directly coupled to the bottom surfaces of the IHS 120 and the first die 110, and the sealant 132 may be directly coupled to the top surface of the package substrate 102.

According to one embodiment, the semiconductor package 100 may be implemented with a 3D architecture (or the like) that includes a 3D stack comprised of the first and second dies 110 and 111a-b, the encapsulation layer 180, the TIM 140, the LHS 130, and the IHS 120. In another embodiment, the semiconductor package 100 may be implemented with other 3D configurations such as a 3D stack with no mold, a stack with multiple bottom dies, and so on. For one embodiment, the semiconductor package 100 is merely one example of an embodiment of a semiconductor packaged system. That is, the semiconductor package 100 is not limited to the illustrated semiconductor packaged system, and thus may be designed/formed with fewer, alternate, or additional packaging components and/or with different interconnecting structures. For example, while one IHS 120, one first die 110, two second dies 111a-b, one encapsulation layer 180, one LHS 130, and one package substrate 102 are illustrated, it is to be appreciated that any number of IHSs 120, first and second dies 110 and 111a-b, encapsulation layers 180, and LHS 130 may be disposed over the package substrate 102.

For one embodiment, the semiconductor package 100 may include a ball grid array (BGA) package, a land grid array (LGA) package, and/or a pin grid array (PGA) package. For one embodiment, as described above, the first die 110 may be coupled to the package substrate 102 via a plurality of solder balls 143, and the second dies 111a-b may be coupled to the first die 110 via a plurality of solder balls 144, where such solder balls 143-144 may be implemented as solder bumps/joints formed from respective microbumps. A solder ball (or joint) formed by soldering of a microbump according to an embodiment may itself be referred to as a “bump” and/or a “microbump.” Additionally, for other embodiments, one or more of the first and second dies 110 and 111a-b and the package substrate 102 may be coupled using an anisotropic conductive film (ACF) or the like.

The package substrate 102 may include a variety of electronic structures formed thereon or therein. In certain embodiments, the package substrate 102 may be an organic substrate made up of one or more layers of polymer base materials, with conducting regions for transmitting signals. For some embodiments, the package substrate 102 may include, but is not limited to, a package, a substrate, a printed circuit board (PCB), and a motherboard. In one embodiment, the package substrate 102 is a PCB. For one embodiment, the PCB is made of an FR-4 glass epoxy base with thin copper foil laminated on both sides. For certain embodiments, a multilayer PCB can be used, with pre-preg and copper foil used to make additional layers. For example, the multilayer PCB may include one or more dielectric layers, where the dielectric layers may be a photosensitive dielectric layer. For one embodiment, the PCB may also include one or more conductive layers, which may further include copper (or metallic) traces, lines, pads, vias, holes, and/or planes.

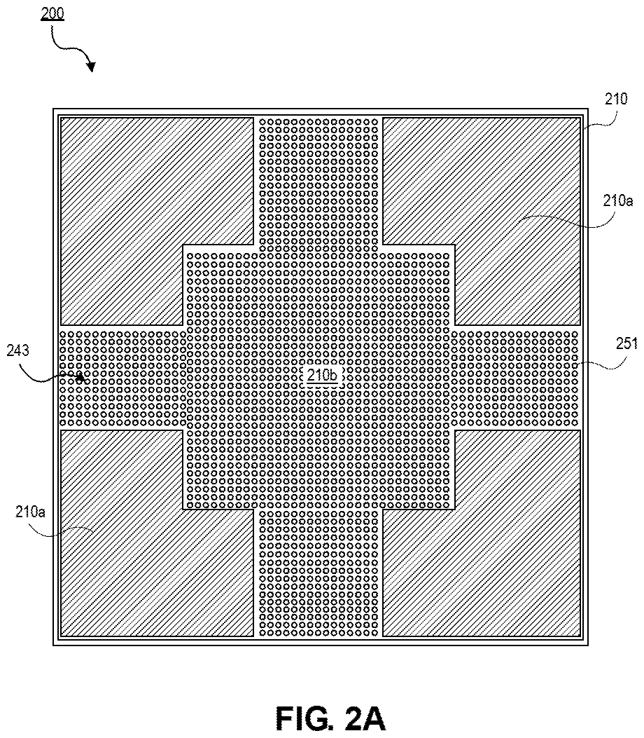

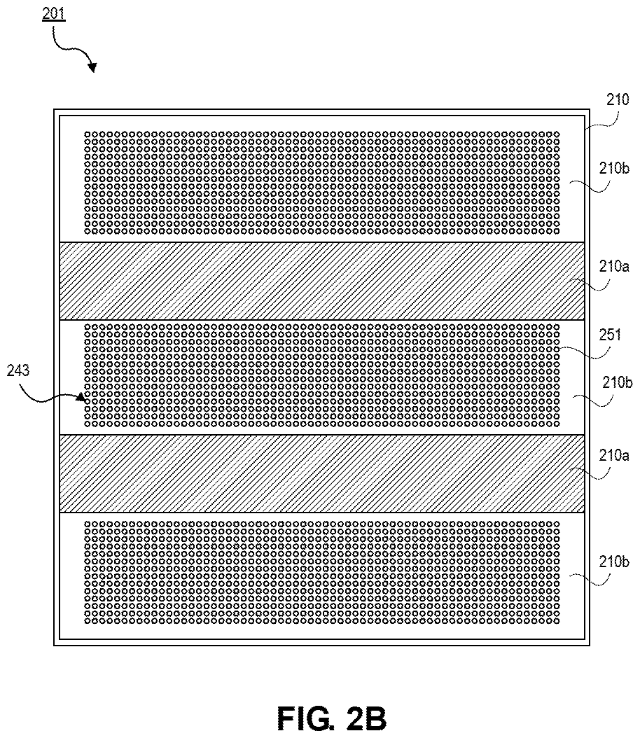

For one embodiment, the stack of first and second dies 110 and 111a-b may be implemented with the first die 110 as the bottom die and the second dies 111a-b as the top dies. Also, in some embodiments, the bottom surface of the first die 110 may include a plurality of first regions 110a and a second region 110b. In these embodiments, the first and second regions 110a-b of the first die 110 may be implemented into one or more first-level interconnect (FLI) patterns (e.g., as shown with the two FLI patterns 200-201 of the first die 210 of FIGS. 2A-2B). For example, the first regions 110a may be the regions on the bottom surface of the first die 110 that interface with the LHS 130 and do not include any of the conductive pads 151 (or the FLIs), thereby the LHS 130 interfaces with the regions on the die side (or the die areas) of the first die 110 that does not have the FLIs. Additionally, these first regions 110a (or die areas) may be maximized by optimizing the design(s) of the FLIs (e.g., the conductive pads 151) to take into account the presence of the LHS 130. Likewise, in these embodiments, the second region 110b may be the region (or regions) on the bottom surface of the first die 110 that includes the conductive pads 151, does not interface with the LHS 130, and interfaces with the solder balls 143 and the underfill layer 154.

In an embodiment, the first and second dies 110 and 111a-b may include, but are not limited to, a semiconductor die, a stack of semiconductor dies, an electronic device (e.g., a wireless device), an integrated circuit (IC), a central processing unit (CPU), a graphic processing unit (GPU), a microprocessor, a platform controller hub (PCH), a memory (e.g., a high-bandwidth memory (HBM)), and/or a field-programmable gate array (FPGA). The first and second dies 110 and 111a-b may be formed from a material such as silicon and have circuitry thereon that is to be coupled to the first die 110 and/or the package substrate 102. Although some embodiments are not limited in this regard, the package substrate 102 may in turn be coupled to another body, for example, a computer motherboard (or the like).

In one embodiment, the first die 110 may have a width that is greater than both widths of the second dies 111a-b. In some embodiments, the second die 111a may have a width (and/or a footprint) that is substantially equal to a width (and/or a footprint) of the second die 111b. While, in other embodiments, the second die 111a may have a width that is different from a width of the second die 111b. For one embodiment, the second die 111a may have a top surface that is substantially coplanar with a top surface of the second die 111b. In other embodiments, the second die 111a may have a thickness that is different from a thickness of the second die 111b (e.g., one of the second dies 111a-b may be a stack of thinner dies). Note that, in some embodiments, the thickness of the region of the TIM 140 disposed over the second die 111a may be substantially equal to or different from the thickness of the region of the TIM 140 that is disposed over the second die 111b.

One or more connections between the package substrate 102 and the first and second dies 110 and 111a-b—e.g., including some or all of the solder bumps 143-144—may include one or more interconnect structures (e.g., a plurality of conductive pads 151), underfill layers (e.g., an underfill layer 154), and so on. In some embodiments, these interconnect structures, such as the conductive pads 151 (or the FLIs), may variously comprise an alloy of nickel, palladium, and tin (and, in some embodiments, copper and/or silver). For one embodiment, the underfill layer 154 may be one or more polymer materials that are injected between the second region 110b of the first die 110 and the top surface of the package substrate 102, and also between the sidewalls of the thermal conductive material 131, the LHS 130, and the sealant 132. That is, the stack of the thermal conductive material 131, the LHS 130, and the sealant 132 disposed below the first regions 110a of the first die 110 may surround the underfill layer 154, the conductive pads 151, and the solder balls 143. In an alternative embodiments, the underfill layer 154 may be a molded underfill (MUF) material or the like.

In some embodiments, the encapsulation layer 180 may be disposed directly over the top surface of the first die 110, where the encapsulation layer 180 surrounds the second dies 111a-b and the solder balls 144. In one embodiment, the encapsulation layer 180 embeds the second dies 111a-b between the top surface of the first die 110 and the bottom surface of the TIM 140. For one embodiment, the encapsulation layer 180 may be planarized with a grinding/polishing process (or the like), where the encapsulation layer 180 may have a top surface that is substantially coplanar with the top surfaces of the second dies 111a-b. In some embodiments, the encapsulation layer 180 may have one or more sidewalls, where the sidewalls may be substantially vertical sidewalls and/or tapered sidewalls.

In one embodiment, the encapsulation layer 180 may include one or more encapsulation materials such as a mold material, an underfill material, a filler material, any similar material(s), and/or any combination thereof. Also, in alternate embodiments, the second dies 111a-b may not be embedded (or encapsulated/surrounded) by an encapsulation layer, and an underfill layer may be disposed between the second dies 111a-b and the first die 110, where the underfill layer may surround the solder balls 144 between the second dies 111a-b and the first die 110 (e.g., the underfill layer may be similar to the underfill layer 154 disposed below the first die 110 and surrounding the solder balls 143).

Furthermore, as shown in FIG. 1, the TIM 140 may be directly coupled onto the top surfaces of the second dies 111a-b and the bottom surface of the IHS 120. In one embodiment, the TIM 140 may be a solder TIM (STIM) such as an indium STIM or the like. In other embodiments, the TIM 140 may include one or more highly thermally conductive materials. For example, the TIM 140 may be a metallic TIM, a STIM, a polymer TIM (PTIM), and/or any similar highly thermally conductive material(s).

In one embodiment, the IHS 120 may be disposed over the TIM 140, the first and second dies 110 and 111a-b, the encapsulation layer 180, the LHS 130, and the package substrate 102. For one embodiment, the IHS 120 may be manufactured (or shaped) to include a lid and a plurality of legs (or sidewalls, pedestals, etc.). For example, the lid of the IHS 120 may be directly disposed on the top surface of the TIM 140, and the legs/sidewalls of the IHS 120 may be disposed over the package substrate 102, where the legs/sidewalls of the IHS 120 may be coupled to the package substrate 102 with the thermal conductive material 131, the LHS 130, and the sealant 132, respectively. In some embodiments, the IHS 120 may be a heatsink, a heat spreader, a heat exchanger, a manifold, a cold plate, and/or any similar thermal solution (or device) that may be used to help transfer the heat from the electrical components of the semiconductor package 100 to the ambient environment (or an additional heat spreader). For one embodiment, the IHS 120 may enclose (or form) a cavity 115 that surrounds the first die 110, the second dies 111a-b, the encapsulation layer 180, the LHS 130, the thermal conductive material 131, and the TIM 140.

In one embodiment, the LHS 130 may be disposed below/underneath the first die 110, where the LHS 130 may laterally extend from below the first regions 110a of the first die 110 to below the bottom surfaces of the legs of the IHS 120. In some embodiments, the LHS 130 may be comprised of one or more thermal materials (or compositions) such as, but are not limited to, graphene sheets, thin heat pipes, thin vapor chambers, and/or the like. In particular, according to these embodiments, the thermal materials of the LHS 130 may have (i) thermal properties that require (or need) high in-plane thermal conductivities, and (ii) size requirements with low thicknesses (or z-heights) that may fit between the first die 110 and the package substrate 102. For example, the high thermal conductivity of the LHS 130 may be approximately 500 W/mK or greater, according to some embodiments. The thickness of the LHS 130 may be approximately 20 um to 100 um according to some embodiments, or less than approximately 300 according to other embodiments.

Furthermore, as shown in FIG. 1, the LHS 130 may be sandwiched (or disposed) between the thermal conductive material 131 above the top surface of the LHS 130 and the sealant 132 below the bottom surface of the LHS 130. In these embodiments, the LHS 130 may be thermally coupled to the first regions 110a of the first die 110 and the legs of the IHS 120 with the thermal conductive material 131. In some embodiments, the thermal conductive material 131 may be a high conductivity adhesive, a high conductivity TIM, and/or the like. For example, the high conductive adhesive may include one or more adhesive materials with a high thermal conductivity (e.g., the high thermal conductivity of the adhesive may have a value of approximately 5 W/mK or greater); such adhesive materials may include conductive materials, metals (such as solder or the like), high-k fillers, epoxies or polymers with highly conductive fillers, and/or any combination therein. Whereas, in one embodiment, the high conductivity TIM may be a STIM, a PTIM, and/or the like. Also, in one embodiment, the LHS 130 may be coupled to the package substrate 102 with the sealant 132, where the sealant 132 may be comprised of one or more adhesive materials such as epoxies, resins (e.g., polymethylpentene (PMP)), silicone, and/or any known adhesive materials.

Note that the semiconductor package 100 may include fewer or additional packaging components based on the desired packaging design.

Referring now to FIG. 2A, a plan illustration of a FLI pattern 200 of a first die 210 is shown, in accordance with an embodiment. In particular, FIG. 2A is an illustration of a bottom view of the first die 210 (i.e., the bottom surface of the first die 210 is shown) with a plurality of first regions 210a, a second region 210b, and a plurality of conductive pads 251, where the first and second regions 210a-b may implement (or form) the illustrated FLI pattern 200, according to one embodiment. The first die 210 with the first and second regions 210a-b and the conductive pads 251 may be substantially similar to the first die 110 with the first and second regions 110a-b and the conductive pads 151 described above in FIG. 1.

In some embodiments, the FLI pattern 200 may be implemented with the first regions 210a positioned on the corner edges of the bottom surface of the first die 210, where the first regions 210a may surround the second region 210b. Note that the first die 210 may implement any number of FLI patterns, such as the FLI pattern 200 of FIG. 2A, the FLI pattern 201 of FIG. 2B, and so on, based on the desired thermal properties and/or electrical interconnection requirements. Also note that, in some embodiments, the first and second regions 210a-b may be patterned to have any desired shapes that may be implemented on the bottom surface of the first die 210.

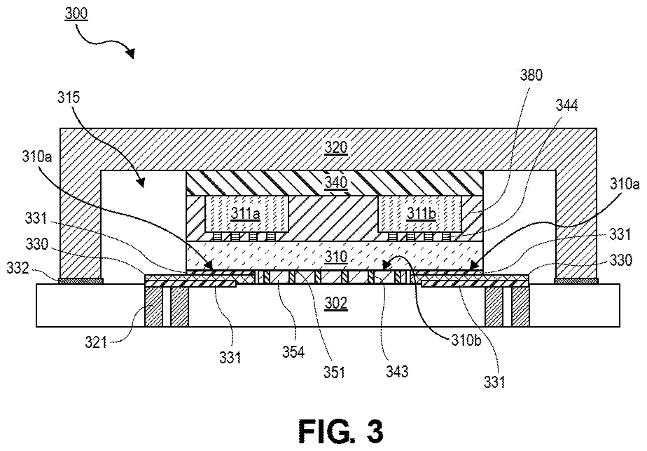

In one embodiment, the conductive pads 251 may be implemented as the FLIs of the first die 210, where the conductive pads 251 (or the FLIs) may be disposed only on the second region 210b, and thus the conductive pads 251 may be patterned (or positioned) based on the patterned shape of the second region 210b. Furthermore, as described above, the first regions 210a may be the regions on the bottom surface of the first die 210 that interface with the LHS described herein (e.g., the LHSs 130 and 330 of FIGS. 1 and 3).

Additionally, the first regions 210a may be maximized by optimizing the design and/or pattern(s) of the conductive pads 251 of the second region 210b and taking into account the presence of the LHS as described herein. The second region(s) 210b may include the conductive pads 251 and interface with a plurality of solder balls 243 and/or an underfill layer as described above.

Note that the FLI pattern 200 of the first die 210 of FIG. 2A may include fewer or additional packaging components based on the desired packaging design.

Referring now to FIG. 2B, a plan illustration of a FLI pattern 201 of a first die 210 is shown, in accordance with an embodiment. In particular, FIG. 2B is an illustration of a bottom view of the first die 210 (i.e., the bottom surface of the first die 210 is shown) with a plurality of first regions 210a, a plurality of second regions 210b, and a plurality of conductive pads 251, where the first and second regions 210a-b may implement (or form) the illustrated FLI pattern 201, according to one embodiment. The first die 210 with the first and second regions 210a-b and the conductive pads 251 may be substantially similar to the first die 110 with the first and second regions 110a-b and the conductive pads 151 described above in FIG. 1.

The FLI pattern 201 of the first die 210 may be similar to the FLI pattern 200 of the first die 210 described above in FIG. 2A, with the exception that the first and second regions 210a-b of FIG. 2B are patterned as alternating stripes (or regions). In some embodiments, the FLI pattern 201 may be implemented with the first regions 210a positioned between the second regions 210b, where both the first and second regions 210a-b extend laterally from one edge of the first die 210 to the opposite edge of the first die 210. Also, as shown in FIG. 2B, the conductive pads 251 may be implemented as the FLIs of the first die 210, where the conductive pads 251 (or the FLIs) may be disposed only on the second regions 210b, and thus the conductive pads 251 may be patterned (or positioned) based on the patterned shape of the second region 210b.

Furthermore, as described above, the first regions 210a may be the regions on the bottom surface of the first die 210 that interface with the LHS described herein (e.g., the LHSs 130 and 330 of FIGS. 1 and 3). Additionally, as described above, the first regions 210a may be maximized by optimizing the patterns of the conductive pads 251 of the second regions 210b and taking into account the presence of the LHS as described herein. Likewise, in these embodiments, the conductive pads 251 of the second regions 210b may be coupled to a plurality of solder balls 243, an underfill layer (e.g., as shown with the underfill layer 154 of FIG. 1), and/or the like.

Note that the FLI pattern 201 of the first die 210 of FIG. 2B may include fewer or additional packaging components based on the desired packaging design.

Referring now to FIG. 3, a cross-sectional illustration of a semiconductor package 300 is shown, in accordance with an embodiment. The semiconductor package 300 may be substantially similar to the semiconductor package 100 described above in FIG. 1, with the exception that the LHS 330 provides a direct heat transfer path from the first die 310 to a plurality of thermal vias 321 disposed within the package substrate 302. Whereas, the LHS 130 provides a direct heat transfer path laterally from the first die 110 towards the legs of the IHS 120 in FIG. 1, the LHS 330 provides the direct heat transfer path laterally from the first die 310 towards the thermal vias 321 of the package substrate 302 in FIG. 3, where the direct heat transfer path may then proceed downward through the thermal vias 321 of the package substrate 302. For example, the thermal vias 321 of the package substrate 302 may be coupled to the LHS 330 to additionally couple the LHS 330 to a board-side cooling solution and/or any other alternative cooling solution.

Likewise, the components of the semiconductor package 300 are substantially similar to the components of the semiconductor package 100 described above in FIG. 1. Accordingly, the package substrate 302, the first die 310 with the first and second regions 310a-b, the second dies 311a-b, the TIM 340, the IHS 320 with the cavity 315, the LHS 330, the thermal conductive material 331, the sealant 332, the solder balls 343-344, and the underfill layer 354 may be substantially similar to the package substrate 102, the first die 110 with the first and second regions 110a-b, the second dies 111a-b, the TIM 140, the IHS 120 with the cavity 115, the LHS 130, the thermal conductive material 131, the sealant 132, the solder balls 143-144, and the underfill layer 154 described above in FIG. 1.

As shown in FIG. 3, the first die 310 may be disposed over the thermal conductive material 331 and the LHS 330. In particular, in these embodiments, the LHS 330 may be directly disposed between and coupled to the thermal conductive material 331, where the thermal conductive material 331 may be directly coupled to the first regions 310a on the bottom surface of the first die 310, the LHS 330, and the top surface of the package substrate 302. In one embodiment, the LHS 330 may be disposed between the first die 310 and the package substrate 302, where the LHS 330 may laterally extend from below the first regions 310a of the first die 310 to above the thermal vias 321 of the package substrate 302, and where the thermal conductive material 331 may couple the LHS 330 to the thermal vias 321 of the package substrate 302.

Furthermore, as shown in FIG. 3, the LHS 330 may be sandwiched (or disposed) between the thermal conductive material 331 above the top surface of the LHS 330 and the thermal conductive material 331 below the bottom surface of the LHS 330. In an embodiment, the LHS 330 may also be coupled to one or more portions of the top surface of the package substrate 302. Additionally, unlike the sealant 132 of FIG. 1, the sealant 332 is disposed between the bottom surfaces of the legs of the IHS 320 and the top surface of the package substrate 302.

For some embodiments, the thermal vias 321 may include one or more materials such as metals (e.g., Cu), highly conductive materials, or the like. In one embodiment, the package substrate 302 may include any number of thermal vias 321 that may be needed for transferring heat away from the LHS 330. For one embodiment, the thermal vias 321 may be implemented with a lithographical plating process or the like. In one embodiment, the top surfaces of the thermal vias 321 may be substantially coplanar to the top surface of the package substrate 302. Also note that, in other embodiments, the semiconductor package 300 may implement the LHS 330 to couple one or more of the first regions 310a of the first die 310 to the thermal vias 321 of the package substrate 302 as shown in FIG. 3, while also implementing the LHS 330 to couple the remaining one or more of the first regions 310a of the first die 310 to the legs of the IHS 320 (as shown in FIG. 1).

Note that the semiconductor package 300 may include fewer or additional packaging components based on the desired packaging design.

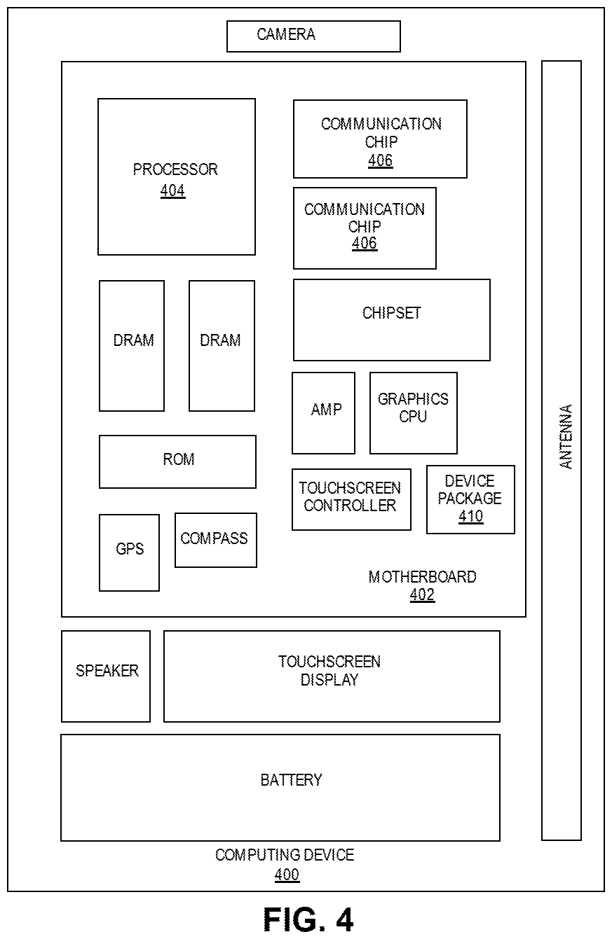

FIG. 4 is an illustration of a schematic block diagram illustrating a computer system 400 that utilizes a device package 410 (or a semiconductor package) with an IHS, a TIM, an encapsulation layer, a plurality of first and second dies, a LHS, a thermal conductive material, a sealant, and a package substrate, according to one embodiment. FIG. 4 illustrates an example of computing device 400. Computing device 400 houses a motherboard 402. Motherboard 402 may include a number of components, including but not limited to processor 404, device package 410 (or semiconductor package), and at least one communication chip 406. Processor 404 is physically and electrically coupled to motherboard 402. For some embodiments, at least one communication chip 406 is also physically and electrically coupled to motherboard 402. For other embodiments, at least one communication chip 406 is part of processor 404.

Depending on its applications, computing device 400 may include other components that may or may not be physically and electrically coupled to motherboard 402. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

At least one communication chip 406 enables wireless communications for the transfer of data to and from computing device 400. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. At least one communication chip 406 may implement any of a number of wireless standards or protocols, including but not limited to Wi-Fi (IEEE 802.11 family), WiMAX (IEEE 802.112 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Computing device 400 may include a plurality of communication chips 406. For instance, a first communication chip 406 may be dedicated to shorter range wireless communications such as Wi-Fi and Bluetooth and a second communication chip 406 may be dedicated to longer range wireless communications such as GPS, EDGE, GPRS, CDMA, WiMAX, LTE, Ev-DO, and others.

Processor 404 of computing device 400 includes an integrated circuit die packaged within processor 404. Device package 410 may be a semiconductor package as described herein. Device package 410 may include, but is not limited to, a substrate, a package substrate, and/or a PCB. In one embodiment, device package 410 may be substantially similar to the semiconductor packages 100 and 300 of FIGS. 1 and 3 described herein. Device package 410 may include implementing LHSs to couple the first die(s) to the legs of the IHS and/or the thermal vias of the package substrate as described herein (e.g., as illustrated and described above with the LHSs 130 and 330 of FIGS. 1 and 3)—or any other components from the figures described herein.

Note that device package 410 may be a single component/device, a subset of components, and/or an entire system, as the materials, features, and components may be limited to device package 410 and/or any other component of the computing device 400 that may need the LHSs as described herein (e.g., the motherboard 402, the processor 404, and/or any other component of the computing device 400 that may need the embodiments of the LHSs and the semiconductor packages as described herein).

For certain embodiments, the integrated circuit die may be packaged with one or more devices on a package substrate that includes a thermally stable RFIC and antenna for use with wireless communications and the device package, as described herein, to reduce the z-height of the computing device. The term “processor” may refer to any device or portion of a device that processes electronic data from registers and/or memory to transform that electronic data into other electronic data that may be stored in registers and/or memory.

At least one communication chip 406 also includes an integrated circuit die packaged within the communication chip 406. For some embodiments, the integrated circuit die of the communication chip 406 may be packaged with one or more devices on a package substrate that includes one or more device packages, as described herein.

In the foregoing specification, embodiments have been described with reference to specific exemplary embodiments thereof. It should be borne in mind, however, that all of these and similar terms are to be associated with the appropriate physical quantities and are merely convenient labels applied to these quantities. It will be evident that various modifications may be made thereto without departing from the broader spirit and scope. The specification and drawings are, accordingly, to be regarded in an illustrative sense rather than a restrictive sense.

The following examples pertain to further embodiments. The various features of the different embodiments may be variously combined with some features included and others excluded to suit a variety of different applications.

The following examples pertain to further embodiments:

Example 1 is a semiconductor package, comprising: a LHS over a package substrate; a first die over the LHS and the package substrate, wherein the first die has a first region and a second region, and wherein the first and second regions are on a bottom surface of the first die; a plurality of second dies over the first die; and an IHS over the plurality of second dies, the first die, the LHS, and the package substrate, wherein the IHS includes a lid and a plurality of legs, and wherein the LHS thermally couples the first region of the first die to the plurality of legs of the IHS.

In example 2, the subject matter of example 1 can optionally include that the LHS laterally extends from below the first region of the first die to below the plurality of legs of the IHS.

In example 3, the subject matter of examples 1-2 can optionally include that the LHS is comprised of a graphene sheet, a heat pipe, or a vapor chamber.

In example 4, the subject matter of examples 1-3 can optionally include that the LHS has a thickness of approximately 20 um to 300 um.

In example 5, the subject matter of examples 1-4 can optionally include that the LHS has a top surface substantially parallel to the bottom surface of the first die and a top surface of the package substrate.

In example 6, the subject matter of examples 1-5 can optionally include the second region of the first die includes a plurality of conductive pads, wherein the plurality of conductive pads of the second region of the first die are conductively coupled to the top surface of the package substrate with a plurality of first solder balls, and wherein the plurality of second dies are conductively coupled to a top surface of the first die with a plurality of second solder balls.

In example 7, the subject matter of examples 1-6 can optionally include a sealant on the top surface of the package substrate, wherein the sealant is directly between the top surface of the package substrate and a bottom surface of the LHS; a thermal conductive material on the top surface of the LHS, wherein the thermal conductive material thermally couples the first region of the first die to the LHS and to the plurality of legs of the IHS; an encapsulation layer over the top surface of the first die, wherein the encapsulation layer surrounds the plurality of second dies and the plurality of second solder balls; a TIM over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and an underfill layer between the second region of the first die and the top surface of the package substrate, wherein the underfill layer surrounds the plurality of conductive pads and the plurality of first solder balls that are coupled to the second region of the first die, and wherein the underfill layer is surrounded by the thermal conductive material, the LHS, and the sealant.

In example 8, the subject matter of examples 1-7 can optionally include that the thermal conductive material has a first portion and a second portion, wherein the first portion is directly between the first region of the first die and the top surface of the LHS, wherein the second portion is directly between the top surface of the LHS and a plurality of bottom surfaces of the plurality of legs of the IHS, and wherein the top surface of the LHS has one or more exposed portions that are not directly coupled to the thermal conductive material.

In example 9, the subject matter of examples 1-8 can optionally include that the thermal conductive material is comprised of a high conductivity adhesive or a high conductivity TIM.

In example 10, the subject matter of examples 1-9 can optionally include that the bottom surface of the first die further includes one or more first regions and one or more second regions, and wherein the one or more first regions are positioned adjacent to the one or more second regions to implement one or more patterns on the bottom surface of the first die

Example 11 is a semiconductor package, comprising: a package substrate with a plurality of thermal vias; a LHS over the plurality of thermal vias and the package substrate; a first die over the LHS and the package substrate, wherein the first die has a first region and a second region, and wherein the first and second regions are on a bottom surface of the first die; a plurality of second dies over the first die; and an IHS over the plurality of second dies, the first die, the LHS, and the package substrate, wherein the IHS includes a lid and a plurality of legs, and wherein the LHS thermally couples the first region of the first die to the plurality of thermal vias of the package substrate.

In example 12, the subject matter of example 11 can optionally include that the LHS laterally extends from below the first region of the first die to above the plurality of thermal vias of the package substrate.

In example 13, the subject matter of examples 11-12 can optionally include that the LHS is comprised of a graphene sheet, a heat pipe, or a vapor chamber.

In example 14, the subject matter of examples 11-13 can optionally include that the LHS has a thickness of approximately 20 um to 300 um.

In example 15, the subject matter of examples 11-14 can optionally include that the LHS has a top surface substantially parallel to the bottom surface of the first die and a top surface of the package substrate.

In example 16, the subject matter of examples 11-15 can optionally include that the second region of the first die includes a plurality of conductive pads, wherein the plurality of conductive pads of the second region of the first die are conductively coupled to the top surface of the package substrate with a plurality of first solder balls, and wherein the plurality of second dies are conductively coupled to a top surface of the first die with a plurality of second solder balls.

In example 17, the subject matter of examples 11-16 can optionally include a sealant on the top surface of the package substrate, wherein the sealant is directly between the top surface of the package substrate and a plurality of bottom surfaces of the plurality of legs of the IHS, and wherein the sealant couples the top surface of the package substrate to the plurality of bottom surfaces of the plurality of legs of the IHS; a thermal conductive material over the LHS and the package substrate, wherein the thermal conductive material has a first portion and a second portion, wherein the first portion is on the top surface of the LHS, wherein the second portion is on the top surface of the package substrate and top surfaces of the plurality of thermal vias of the package substrate, and wherein the thermal conductive material thermally couples the first region of the first die to the LHS and to the plurality of thermal vias of the package substrate; an encapsulation layer over the top surface of the first die, wherein the encapsulation layer surrounds the plurality of second dies and the plurality of second solder balls; a TIM over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and an underfill layer between the second region of the first die and the top surface of the package substrate, wherein the underfill layer surrounds the plurality of conductive pads and the plurality of first solder balls that are coupled to the second region of the first die, and wherein the underfill layer is surrounded by the thermal conductive material and the LHS.

In example 18, the subject matter of examples 11-17 can optionally include that the first portion of the thermal conductive material is directly between the first region of the first die and the top surface of the LHS, wherein the second portion of the thermal conductive material is directly between a bottom surface of the LHS and the top surfaces of the package substrate and the plurality of thermal vias, and wherein the top surface of the LHS has one or more exposed portions that are not directly coupled to the thermal conductive material.

In example 19, the subject matter of examples 11-18 can optionally include that the thermal conductive material is comprised of a high conductivity adhesive or a high conductivity TIM.

In example 20, the subject matter of examples 11-19 can optionally include that the bottom surface of the first die further includes one or more first regions and one or more second regions, and wherein the one or more first regions are positioned adjacent to the one or more second regions to implement one or more patterns on the bottom surface of the first die.

Example 21 is a semiconductor package, comprising: a package substrate with a cooling solution and a plurality of thermal vias; a plurality of LHSs over the plurality of thermal vias and the package substrate; a plurality of first dies over the plurality of LHSs and the package substrate, wherein the plurality of first dies have a plurality of first regions and a plurality of second regions, and wherein the plurality of first and second regions are on bottom surfaces of the plurality of first dies; a plurality of second dies over the plurality of first dies; and an IHS over the plurality of second dies, the plurality of first dies, the plurality of LHSs, and the package substrate, wherein the IHS includes a lid and a plurality of legs, and wherein the plurality of LHSs thermally couple the plurality of first regions of the plurality of first dies to the plurality of legs of the IHS or to the plurality of thermal vias of the package substrate.

In example 22, the subject matter of example 21 can optionally include the plurality of LHSs are comprised of a graphene sheet, a heat pipe, or a vapor chamber, wherein the plurality of LHSs include a first LHS and a second LHS, wherein the first LHS laterally extends from below the plurality of first regions of the plurality of first dies to below the plurality of legs of the IHS, wherein the second LHS laterally extends from below the plurality of first regions of the plurality of first dies to above the plurality of thermal vias of the package substrate, wherein the plurality of LHSs have a thickness of approximately 20 um to 300 um, and wherein the plurality of LHSs have top surfaces substantially parallel to the bottom surfaces of the plurality of first dies and a top surface of the package substrate.

In example 23, the subject matter of examples 21-22 can optionally include that the plurality of second regions of the plurality of first dies includes a plurality of conductive pads, wherein the plurality of conductive pads of the plurality of second regions of the plurality of first dies are conductively coupled to the top surface of the package substrate with a plurality of first solder balls, and wherein the plurality of second dies are conductively coupled to top surfaces of the plurality of first dies with a plurality of second solder balls.

In example 24, the subject matter of examples 21-23 can optionally include that a sealant on the top surface of the package substrate, wherein the sealant couples the plurality of legs of the IHS to the package substrate; a thermal conductive material over the plurality of LHSs and the package substrate, wherein the thermal conductive material thermally couples the plurality of first regions of the plurality of first dies to the plurality of LHSs, wherein the thermal conductive material thermally couples the first LHS to the plurality of legs of the IHS, and wherein the thermal conductive material thermally couples the second LHS to the plurality of thermal vias of the package substrate; an encapsulation layer over the top surfaces of the plurality of first dies, wherein the encapsulation layer surrounds the plurality of second dies and the plurality of second solder balls; a TIM over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and an underfill layer between the plurality of second regions of the plurality of first dies and the top surface of the package substrate, wherein the underfill layer surrounds the plurality of conductive pads and the plurality of first solder balls that are coupled to the plurality of second regions of the plurality of first dies, and wherein the underfill layer is surrounded by the thermal conductive material, the LHS, or the sealant.

In example 25, the subject matter of examples 21-24 can optionally include that the top surfaces of the plurality of LHSs have one or more exposed portions that are not directly coupled to the thermal conductive material, wherein the thermal conductive material is comprised of a high conductivity adhesive or a high conductivity TIM, and wherein the plurality of first regions are positioned adjacent to the plurality of second regions to implement one or more patterns on the bottom surfaces of the plurality of first dies.

In the foregoing specification, methods and apparatuses have been described with reference to specific exemplary embodiments thereof. It will be evident that various modifications may be made thereto without departing from the broader spirit and scope. The specification and drawings are, accordingly, to be regarded in an illustrative sense rather than a restrictive sense.

What is claimed is:

1. A semiconductor package, comprising:
a lateral heat spreader (LHS) over a package substrate;
a first die over the LHS and the package substrate, wherein the first die has a first region and a second region, and wherein the first and second regions are on a bottom surface of the first die;
a plurality of second dies over the first die; and
an integrated heat spreader (IHS) over the plurality of second dies, the first die, the LHS, and the package substrate, wherein the IHS includes a lid and a plurality of legs, and wherein the LHS thermally couples the first region of the first die to the plurality of legs of the IHS.

2. The semiconductor package of claim 1, wherein the LHS laterally extends from below the first region of the first die to below the plurality of legs of the IHS.

3. The semiconductor package of claim 1, wherein the LHS is comprised of a graphene sheet, a heat pipe, or a vapor chamber.

4. The semiconductor package of claim 1, wherein the LHS has a thickness of approximately 20 um to 300 um.

5. The semiconductor package of claim 1, wherein the LHS has a top surface substantially parallel to the bottom surface of the first die and a top surface of the package substrate.

6. The semiconductor package of claim 5, wherein the second region of the first die includes a plurality of conductive pads, wherein the plurality of conductive pads of the second region of the first die are conductively coupled to the top surface of the package substrate with a plurality of first solder balls, and wherein the plurality of second dies are conductively coupled to a top surface of the first die with a plurality of second solder balls.

7. The semiconductor package of claim 6, further comprising:
a sealant on the top surface of the package substrate, wherein the sealant is directly between the top surface of the package substrate and a bottom surface of the LHS;
a thermal conductive material on the top surface of the LHS, wherein the thermal conductive material thermally couples the LHS to the first region of the first die and to the plurality of legs of the IHS;
an encapsulation layer over the top surface of the first die, wherein the encapsulation layer surrounds the plurality of second dies and the plurality of second solder balls;
a thermal interface material (TIM) over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and
an underfill layer between the second region of the first die and the top surface of the package substrate, wherein the underfill layer surrounds the plurality of conductive pads and the plurality of first solder balls that are coupled to the second region of the first die, and wherein the underfill layer is surrounded by the thermal conductive material, the LHS, and the sealant.

8. The semiconductor package of claim 7, wherein the thermal conductive material has a first portion and a second portion, wherein the first portion is directly between the first region of the first die and the top surface of the LHS, wherein the second portion is directly between the top surface of the LHS and a plurality of bottom surfaces of the plurality of legs of the IHS, and wherein the top surface of the LHS has one or more exposed portions that are not directly coupled to the thermal conductive material.

9. The semiconductor package of claim 8, wherein the thermal conductive material is comprised of a high conductivity adhesive or a high conductivity TIM.

10. The semiconductor package of claim 1, wherein the bottom surface of the first die further includes one or more first regions and one or more second regions, and wherein the one or more first regions are positioned adjacent to the one or more second regions to implement one or more patterns on the bottom surface of the first die.

11. A semiconductor package, comprising:
a package substrate with a plurality of thermal vias;
a LHS over the plurality of thermal vias and the package substrate;
a first die over the LHS and the package substrate, wherein the first die has a first region and a second region, and wherein the first and second regions are on a bottom surface of the first die;
a plurality of second dies over the first die; and
an IHS over the plurality of second dies, the first die, the LHS, and the package substrate, wherein the IHS includes a lid and a plurality of legs, and wherein the LHS thermally couples the first region of the first die to the plurality of thermal vias of the package substrate.

12. The semiconductor package of claim 11, wherein the LHS laterally extends from below the first region of the first die to above the plurality of thermal vias of the package substrate.

13. The semiconductor package of claim 11, wherein the LHS is comprised of a graphene sheet, a heat pipe, or a vapor chamber.

14. The semiconductor package of claim 11, wherein the LHS has a thickness of approximately 20 um to 300 um.

15. The semiconductor package of claim 11, wherein the LHS has a top surface substantially parallel to the bottom surface of the first die and a top surface of the package substrate.

16. The semiconductor package of claim 15, wherein the second region of the first die includes a plurality of conductive pads, wherein the plurality of conductive pads of the second region of the first die are conductively coupled to the top surface of the package substrate with a plurality of first solder balls, and wherein the plurality of second dies are conductively coupled to a top surface of the first die with a plurality of second solder balls.

17. The semiconductor package of claim 16, further comprising:
a sealant on the top surface of the package substrate, wherein the sealant is directly between the top surface of the package substrate and a plurality of bottom surfaces of the plurality of legs of the IHS, and wherein the sealant couples the top surface of the package substrate to the plurality of bottom surfaces of the plurality of legs of the IHS;
a thermal conductive material over the LHS and the package substrate, wherein the thermal conductive material has a first portion and a second portion, wherein the first portion is on the top surface of the LHS, wherein the second portion is on the top surface of the package substrate and top surfaces of the plurality of thermal vias of the package substrate, and wherein the thermal conductive material thermally couples the LHS to the first region of the first die and to the plurality of thermal vias of the package substrate;
an encapsulation layer over the top surface of the first die, wherein the encapsulation layer surrounds the plurality of second dies and the plurality of second solder balls;
a TIM over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and
an underfill layer between the second region of the first die and the top surface of the package substrate, wherein the underfill layer surrounds the plurality of conductive pads and the plurality of first solder balls that are coupled to the second region of the first die, and wherein the underfill layer is surrounded by the thermal conductive material and the LHS.

18. The semiconductor package of claim 17, wherein the first portion of the thermal conductive material is directly between the first region of the first die and the top surface of the LHS, wherein the second portion of the thermal conductive material is directly between a bottom surface of the LHS and the top surfaces of the package substrate and the plurality of thermal vias, and wherein the top surface of the LHS has one or more exposed portions that are not directly coupled to the thermal conductive material.

19. The semiconductor package of claim 18, wherein the thermal conductive material is comprised of a high conductivity adhesive or a high conductivity TIM.

20. The semiconductor package of claim 19, wherein the bottom surface of the first die further includes one or more first regions and one or more second regions, and wherein the one or more first regions are positioned adjacent to the one or more second regions to implement one or more patterns on the bottom surface of the first die.

21. A semiconductor package, comprising:
a package substrate with a cooling solution and a plurality of thermal vias;
a plurality of LHSs over the plurality of thermal vias and the package substrate;
a plurality of first dies over the plurality of LHSs and the package substrate, wherein the plurality of first dies have a plurality of first regions and a plurality of second regions, and wherein the plurality of first and second regions are on bottom surfaces of the plurality of first dies;
a plurality of second dies over the plurality of first dies; and
an IHS over the plurality of second dies, the plurality of first dies, the plurality of LHSs, and the package substrate, wherein the IHS includes a lid and a plurality of legs, and wherein the plurality of LHSs thermally couple the plurality of first regions of the plurality of first dies to the plurality of legs of the IHS, or the plurality of LHSs thermally couple the plurality of first regions of the plurality of first dies to the plurality of thermal vias of the package substrate.

22. The semiconductor package of claim 21, wherein, when the plurality of LHSs are coupled to the plurality of thermal vias, the plurality of thermal vias further couple the plurality of LHSs to the cooling solution, and wherein the plurality of LHSs are comprised of a plurality of graphene sheets, a plurality of heat pipes, or a plurality of vapor chambers, wherein the plurality of LHSs include a first LHS and a second LHS, wherein the first LHS laterally extends from below the plurality of first regions of the plurality of first dies to below the plurality of legs of the IHS, wherein the second LHS laterally extends from below the plurality of first regions of the plurality of first dies to above the plurality of thermal vias of the package substrate, wherein the plurality of LHSs have a thickness of approximately 20 um to 300 um, and wherein the plurality of LHSs have top surfaces substantially parallel to the bottom surfaces of the plurality of first dies and a top surface of the package substrate.

23. The semiconductor package of claim 22, wherein the plurality of second regions of the plurality of first dies includes a plurality of conductive pads, wherein the plurality of conductive pads of the plurality of second regions of the plurality of first dies are conductively coupled to the top surface of the package substrate with a plurality of first solder balls, and wherein the plurality of second dies are conductively coupled to top surfaces of the plurality of first dies with a plurality of second solder balls.

24. The semiconductor package of claim 23, further comprising:
a sealant on the top surface of the package substrate, wherein the sealant couples the plurality of legs of the IHS to the package substrate;
a thermal conductive material over the plurality of LHSs and the package substrate, wherein the thermal conductive material thermally couples the plurality of first regions of the plurality of first dies to the plurality of LHSs, wherein the thermal conductive material thermally couples the first LHS to the plurality of legs of the IHS, and wherein the thermal conductive material thermally couples the second LHS to the plurality of thermal vias of the package substrate;
an encapsulation layer over the top surfaces of the plurality of first dies, wherein the encapsulation layer surrounds the plurality of second dies and the plurality of second solder balls;
a TIM over the encapsulation layer and the plurality of second dies, wherein the TIM is directly between the lid of the IHS and the encapsulation layer and the plurality of second dies, and wherein the TIM thermally couples top surfaces of the plurality of second dies to a bottom surface of the lid of the IHS; and
an underfill layer between the plurality of second regions of the plurality of first dies and the top surface of the package substrate, wherein the underfill layer surrounds the plurality of conductive pads and the plurality of first solder balls that are coupled to the plurality of second regions of the plurality of first dies, and wherein the underfill layer is surrounded by the thermal conductive material, the LHS, or the sealant.

25. The semiconductor package of claim 24, wherein the top surfaces of the plurality of LHSs have one or more exposed portions that are not directly coupled to the thermal conductive material, wherein the thermal conductive material is comprised of a high conductivity adhesive or a high conductivity TIM, and wherein the plurality of first regions are positioned adjacent to the plurality of second regions to implement one or more patterns on the bottom surfaces of the plurality of first dies.
